(19) United States
(12) Patent Application Publication
(10) Pub. No.: US 2013/0140838 A1
(43) Pub. Date: Jun. 6, 2013

(54) MOBILE VACUUM CARRIERS FOR THIN WAFER PROCESSING

(71) Applicants: David Xuan-Qi Wang, Fremont, CA (US); Mehrdad Moslehi, Los Altos, CA (US)

(72) Inventors: David Xuan-Qi Wang, Fremont, CA (US); Mehrdad Moslehi, Los Altos, CA (US)

(73) Assignee: SOLEXEL, INC., Milpitas, CA (US)

(21) Appl. No.: 13/515,848

(22) PCT Filed: Dec. 15, 2010
(86) PCT No.: PCT/US10/60591

§ 371 Date: Dec. 24, 2012

Related U.S. Application Data
(60) Provisional application No. 61/286,638, filed on Dec. 15, 2009.

(51) Int. Cl. H01L 21/677

(52) U.S. Cl. CPC H01L 21/677
USPC 294/188

(57) ABSTRACT

This disclosure presents mobile vacuum carriers that may be used to support thin substrates that would otherwise be too brittle to transport and process. This disclosure relates to the processing of thin semiconductor substrates and has particular applicability to the fields of photovoltaic solar cells, semiconductor microelectronic integrated circuits, micro-electro-mechanical systems (MEMS), optoelectronic devices (such as light-emitting diodes, lasers, photo detectors), data storage devices, etc.

### CROSS-REFERENCE TO RELATED APPLICATIONS

This application claims priority to U.S. Provisional Patent Application Ser. No. 61/286,638, which is hereby incorporated by reference in its entirety.

### FIELD

This disclosure relates in general to the field of processing ultra-thin substrates. More specifically, it relates to the processing of semiconductor substrates with thicknesses in the range of about 1 to 100 microns, although it is also applicable to substrates even thinner than 1 micron or even thicker than 100 microns. These substrates may be used for, among other things, photovoltaic solar cells, semiconductor microelectronic integrated circuits, micro-electro-mechanical systems (MEMS), optoelectronic devices (such as light-emitting diodes, lasers, photo detectors), data storage devices, etc. Even more specifically, the disclosure relates to apparatus, manufacturing and application methods, and systems of mobile and transportable vacuum (or low-pressure clamped) carriers for temporarily holding, supporting, handling, transporting, storing, and processing ultra-thin substrates. These devices may be applied to both single-wafer and batch processing systems. Such mobile vacuum carriers (MVCs) enable supporting, handling transporting, processing, etc. while ensuring substantially reduced yield losses due to substrate breakage.

### BACKGROUND

Thin semiconductor substrates are highly advantageous in high-performance semiconductor microelectronics, system-on-a-chip (SOC), silicon-on-insulator (SOI), MEMS, power electronics, flexible ICs, photovoltaics, and optoelectronics applications, among others.

Semiconductor wafers, such as monocrystalline silicon wafers tend to be brittle and easy to break from stresses and micro-cracks when their thickness is reduced, particularly to much less than 150 microns. In addition, with reduced mechanical rigidity of a thin wafer, it becomes flexible and behaves more like a flexible piece of thin foil. As a result, it is difficult and problematic when they are handled and processed in normal semiconductor microelectronic or photovoltaic process equipment designed to process wafers with regular thicknesses (e.g., 150 microns to 1000 microns).

In order to use existing commercially available wafer processing equipment for thin or ultra-thin wafer handling and processing, methods have been developed that support the thin wafer on a carrier plate. The bonding of the thin wafer to its carrier may be made temporary or permanent. Temporary bonding and debonding methods include using mobile electrostatic chucks and adhesive films. Such techniques usually add significant cost to the overall manufacturing cost of the semiconductor devices using such ultra-thin substrates. Other related thin wafer handling methods, such as using edge gripping, Bernoulli effects, and ultrasonic effects have also been developed. However, these techniques usually suffer from incompatibility with high temperature processing and/or processing in corrosive environments (such as corrosive wet chemistries).

Crystalline (both mono-crystalline and multi-crystalline) silicon (c-Si) wafers are also widely used in the silicon-based photovoltaic market, mainly due to higher efficiencies and synergies with the established microelectronics industry and supply chain. The trend in the mainstream c-Si wafer solar cell industry has been to scale down wafer thicknesses to below 200 microns (in order to reduce the amount of silicon material in grams per watt of solar cell rated peak power, thus, reducing the overall manufacturing cost of the solar photovoltaic power modules). For example, the leading edge monocrystalline silicon wafer solar cells are projected to scale down to a thinness of 120 microns by 2012, from a current wafer thickness of 140 to 200 microns. Technologies are also been developed that use less than 100 micron c-Si foil to make high efficiency solar cells. In addition, thin substrates may be a requirement to make partially see-through c-Si solar cells for building integrated photovoltaic (BIPV) products. Thin c-Si solar cells are usually much larger than any other stand-alone thin semiconductor or MEMS devices (chips): typically 200 to 500 cm² for solar cells vs. 1 to several cm² (or even smaller) for semiconductor microelectronic and MEMS chips). Typical silicon solar cell sizes are 210 mm×210 mm, 156 mm×156 mm, and 125 mm×125 mm squares (or pseudo squares).

Some of the challenges for handling and processing thin c-Si solar cell substrates using known methods with or without mobile thin-wafer carriers are: breakage (mechanical yield loss) initiated by handling/processing stresses; impacts and existing micro cracks; especially at substrate edges; the fact that most current solar cell equipment is capable of handling only substrates thicker than about 120 microns; the much higher throughput and much lower cost requirements of solar cell manufacturing (compared to microelectronics, optoelectronics, and MEMS), which makes many existing thin substrate handling methods difficult or too expensive to be applied in solar cell manufacturing; and high temperature (>300° C.) process requirements, which make some of the thin wafer handling methods difficult to apply in solar cell manufacturing. As an example, thermal oxidation and diffusion/anneal processes are usually done at around 850° C. to 1100° C., and known mobile thin-wafer carriers could not be used in such high-temperature environments. In the case that a mobile thin-wafer carrier is used, not only must the carrier structural materials survive high temperatures, but the thermal expansion mismatch between the thin wafer and its carrier must be carefully managed. More specifically, one must ensure that there would be no appreciable thermal coefficient of expansion (TCE) mismatch between the support carrier and the semiconductor substrate being processed.

The thin wafers (like wafers with regular thicknesses) need to be processed in dry and/or wet chemical environments for etching, deposition, coating, electroplating, etc. Therefore, if mobile thin-wafer carriers are used, it is advantageous if the structural materials of the carriers and adhesives used are inert (or highly corrosion or etch resistant) and compatible with the wet or dry chemical processing environments. In order to substantially reduce the impact on manufacturing cost, such mobile thin-wafer carriers should be reusable over many substrates.

### SUMMARY

Therefore, it is an object of the present disclosure to provide mobile thin-wafer carriers that address some or all of the foregoing problems with known carriers.

The present disclosure provides apparatus, manufacturing methods, and application methods of supporting, handling, transporting, storing, and processing thin and fragile semiconductor wafers for making low-cost photovoltaic solar cells. However, the methods, apparatus, and devices in this disclosure could also be applied in a wide range of other applications including making semiconductor microelectronic chips, system-on-a-chip (SOC), MEMS devices, discrete devices, power electronics, flexible ICs, data storage devices, optoelectronic devices (e.g., LEDs, lasers, photo detectors), and other high-technology products using monolithic integrated manufacturing technologies.

### BRIEF DESCRIPTION OF THE DRAWINGS

The features, nature, and advantages of the disclosed subject matter will become more apparent from the detailed description set forth below when taken in conjunction with the drawings, in which like reference numerals indicate like features and wherein:

FIG. 1 illustrates a cross-sectional schematic drawing of a single-wafer MVC of the present disclosure and a vacuum-bonded thin wafer;

FIGS. 2A and 2B illustrate a cross-sectional schematic drawing of a single-sided MVC tray and a double-sided MVC tray and multiple vacuum-bonded thin wafers;

FIG. 3 illustrates a top-view SEM photo of an MVC;

FIGS. 4A and 4B illustrate a top-view SEM photo and a cross-sectional schematic drawing of another MVC;

FIGS. 5A and 5B illustrate a top-view SEM photo and a cross-sectional schematic drawing of yet another MVC, which allows handling non-flat thin wafers with proper alignment;

FIGS. 6A and 6B illustrate a top-view SEM photo and a cross-sectional schematic drawing of yet another MVC;

FIG. 7 shows a flowchart and cross-sectional schematic drawings of steps in the fabrication of one type of MVC;

FIG. 8 shows a flowchart and cross-sectional schematic drawings of steps in the fabrication of another type of MVC;

FIGS. 9A-9D illustrate an apparatus of the present disclosure and the sequence of using it for making the vacuum bonding of a thin wafer and a MVC;

FIGS. 10A-10D illustrate an apparatus of the present disclosure and the sequence of using it for debonding/separating of a thin wafer from an MVC;

FIGS. 11A-11E illustrate another apparatus of the present disclosure and the sequence of using it for making the vacuum bonding of a thin wafer and an MVC;

FIGS. 12A-12D illustrate another apparatus of the present disclosure and the sequence of using it for debonding/separating of a thin wafer from a MVC and include cross-sectional schematic drawings after key steps;

FIGS. 13A-13C illustrate another apparatus of the present disclosure and the sequence of using it for making the vacuum bonding of multiple thin wafers and a MVC tray;

FIGS. 14A-14D illustrate another apparatus of the present disclosure and the sequence of using it for debonding/separating of multiple thin wafers from a MVC tray;

FIG. 15 illustrates a cross-sectional schematic drawing of a solar cell; and

FIG. 16 illustrates an application of MVC in semiconductor microelectronic integrated circuits.

### DETAILED DESCRIPTION

Although the present disclosure is described with reference to specific embodiments, one skilled in the art could apply the principles discussed herein to other areas and/or embodiments without undue experimentation.

In accordance with the present disclosure, MVCs are used as very cost-effective and reliable mechanical supports for the temporary handling and processing of thin wafers/substrates. Such carriers can be used to support wafer processing in high temperature, wet, plasma, low-pressure, and many other process conditions. High-density arrayed micro-scale cavities may be used on the MVC surface to serve as distributed vacuum clamp/suction cups for temporary bonding of a thin wafer through a sequence of vacuum evacuation and venting process.

The bonding of the carrier to a thin wafer is made possible by fault tolerant, distributed, and high-density (i.e., hundreds to many thousands in some embodiments) micro-scale vacuum cavities on the carrier surface. The bonding (or attachment) of the thin wafer and its support carrier is achieved in a vacuum (or reduced-pressure) chamber, in where the air in the micro-scale vacuum cavities is partially or substantially pumped out. After making the contact of a thin wafer and the carrier top surface, the micro-scale vacuum cavities are enclosed by the thin substrate being placed on the carrier. A pressure differential is then formed as the chamber is vented and keeps them temporarily bonded together when they are brought into an atmospheric pressure or an environment with a pressure higher than the initial bonding pressure. After one or a series of wafer handling, transport, and/or processing steps, the thin wafer can be easily detached or debonded from the MVC by placing the stack in a vacuum chamber, pumping out the air from the vacuum chamber, and separating the substrate from the carrier in the vacuum chamber. The MVC may be reused again and again over many reuse cycles for handling and processing additional thin wafers.

The MVCs of the present disclosure may be made of many different structural materials, including but not limited to semiconductors, ceramics, metals, insulators, and polymer substrates.

The micro vacuum cavities on the carrier surface may be made by chemical etching with a patterned masking layer, random texturing by chemical etching, plasma etching, reactive-ion etching, laser drilling (laser ablation or laser-assisted chemical etching), ion beam milling (or ion beam etching), mechanical drilling, hot embossing, stamping, injection molding simply using a porous surface, or other known methods. In an optional configuration, a thin mechanical guard structure may be machined/fabricated on the peripheral region of the micro-scale vacuum cavity array to serve as a position constraint for an unbounded thin wafer to sit on the MVC. A corrosion-resistant (and/or etch-resistant and/or a stiction-resistant) surface coating layer may also be used to serve one or more of the following functions: a soft, flexible, or compliant layer for better vacuum sealing, such as thin polymers; a wearing resistant layer, such as LPCVD silicon nitride, aluminum oxide, Teflon, etc.; a chemically inert coating to prevent the carrier from chemical etching during the thin wafer process, such as LPCVD silicon nitride, Teflon, etc.; a lubrication layer for easier debond/release, such as a thin Teflon (or another suitable polymeric) layer.

A pre-structured or processed thin wafer with out-of-plane microstructures may be temporarily bonded to a supporting MVC with precise alignment during vacuum bonding.

The MVC may be about the same size or slightly larger than the thin wafer to be bonded (to protect the thin substrate edges in the latter case); however, it may be thicker and more rigid. An MVC may be a single wafer carrier. Alternatively, the MVC may also be in a tray form that allows multiple-wafer carrying for a batch or a hybrid batch/in-line manufacturing process. Furthermore, the MVC of the present disclosure could be in a conveyer form, on which a stream of thin wafers are continuously handled and processed.

The present disclosure provides for a thin-silicon wafer based solar cell that uses MVCs for temporary support, handling, transferring, and cell processing applications. Furthermore, the micro-scale vacuum cavities, regularly or randomly made, may also be designed to facilitate light trapping to reduce the reflective optical loss on the solar cell front surface without increasing the silicon front surface area. As a result, this may provide increased overall cell efficiency.

Some advantages of the MVCs of the present disclosure include: simple to use (both to reliably clamp and declamp); simple to make, by using a variety of carrier materials (either the same material as the semiconductor device substrate or dissimilar materials); high-temperature-compatible with the thin substrate (an MVC may be made from same material as the thin wafer so that thermal mismatch during high temperature process is completely avoided and the clamping force is preserved); allows temporary bonding of conductor, insulator, or semiconductor structural and surface materials; allows aligned bonding to pre-structured or pre-processed thin wafers with out-of-plane microstructures; low cost to fabricate compared to known mobile thin-wafer carriers; very low amortized cost over many reuse cycles for temporary MVC applications; flexible MVC design (could be a single wafer carrier, a multiple wafer carrier tray or a continuous wafer conveyor that allows in-line thin wafer process, etc.).

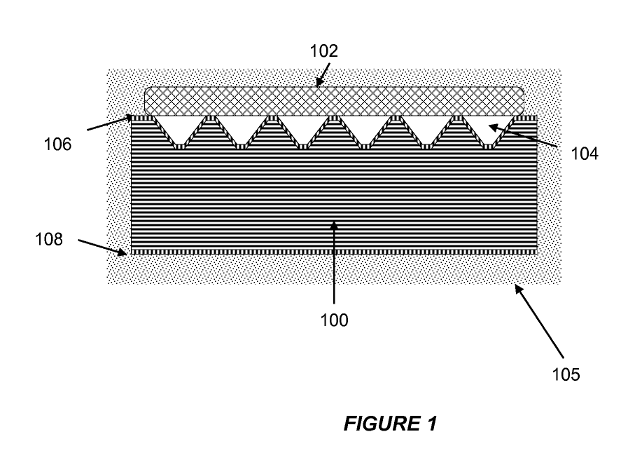

FIG. 1 illustrates a cross-sectional schematic drawing of single-wafer MVC 100 and vacuum-bonded thin wafer 102. The top side of MVC 100 consists of a distributed plurality of vacuum cavities 104, which are used to vacuum bond (or clamp) a thin wafer temporarily to a surface (either top or bottom surface) of MVC 100 by excluding ambient air pressure 105. In some embodiments, many micro-scale cavities are employed: in the range of thousands to tens of thousands of cavities having apertures and/or depths in the range of approximately one micron to tens of microns. MVC 100 may be re-used over many cycles after proper cleaning and reconditioning (if necessary) after each or multiple use cycles. MVC 100 may be used for bonding a thin wafer on either its top side or its bottom side. It may also be used to transfer wafer 102 from being bonded on one side to being bonded on the other to allow processing both sides of wafer 102. Methods of making cavities 104 include but are not limited to chemical etching with a patterned masking layer, laser ablation (or laser etching), EDM, milling, abrasive blasting, stamping, hot-embossing, and grinding with a non-planar surface. The cavity sizes (aperture openings) may be in the range of 1 micron to as large as 1 mm, and their depths may be in the same approximate range. It may be advantageous for these dimensions (particularly the aperture dimension) to be not much larger than the thickness of wafer 102 (in order to prevent localized deformation of wafer 102).

Optional thin surface coating layers may be employed on either or both the top (top coating 106) and bottom (bottom coating 108) of MVC 100. Top coating 106 may be conformally deposited/coated on cavities 104 surfaces. Surface coating layers 106 and 108 in some embodiments may be: a soft, flexible, or compliant layer for better vacuum sealing, such as thin polymers; a wear-resistant layer, such as LPCVD silicon nitride, aluminum oxide, Teflon etc.; a chemically inert or etch-resistant coating to prevent the carrier from chemical etching during the thin wafer process, such as LPCVD silicon nitride, Teflon, etc., or a lubrication layer for easier debond/release, such as a thin Teflon layer.

To minimize the local deformation/bending of the thin wafer on top of the sealed vacuum micro cavities, the micro-scale cavity sizes may be small. Alternatively (or in conjunction), the depth of the vacuum cavities may be shallow, so that the maximum thin wafer local deformation under vacuum is limited when its bottom surface makes contact with the micro cavity bottom surfaces. For example, for a micro-scale cavity depth of 5 microns, the maximum local deformation of the thin wafer is also 5 microns (for a large micro-cavity aperture).

It is to be noted, the terms “low pressure”, “reduced pressure”, and “vacuum” are relative in this disclosure. As long as there is a pressure differential across the thin wafer, the thin wafer will be securely clamped and supported on the MVC. For example, for a 760 Torr atmospheric pressure, any pressure less than 760 Torr sealed in micro-scale vacuum cavities will work in ambient temperature. However, if high temperature process is involved, the pressure increase in the sealed vacuum micro cavities at increased processing temperature needs to be taken into account, in which case, the initial sealing pressure in the cavities need to be lower.

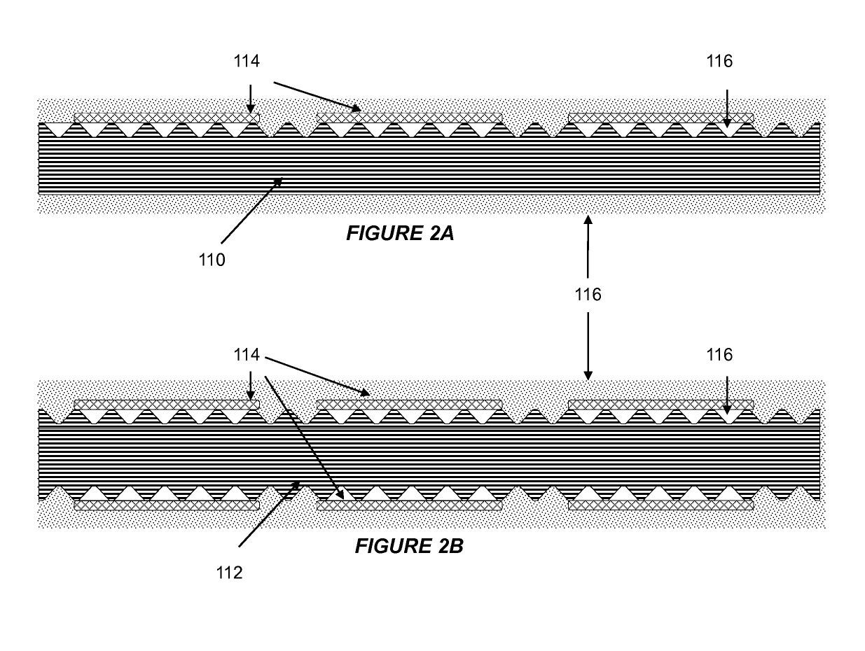

FIGS. 2A and 2B illustrate cross-sectional schematic drawings of single-sided MVC tray 110 and double-sided MVC tray 112, respectively, along with multiple vacuum bonded thin wafers 114 in an ambient air pressure environment 115. The MVC trays in these FIGURES may optionally have the surface coating and other features described in connection with FIG. 1, and further allow batch processing of multiple wafers. In addition, as shown in FIG. 2B, cavity structures 116 may be made on both side of the tray for higher throughput and more efficient thin wafer processing. In this case, MVC tray 112 may be supported from its peripheral during a batch process, so that the wafers or both sides may be exposed to process environments. For simplicity of the drawings, the peripheral support structure of MVC tray 112 is not shown in the FIGURE. As another option, cavities 116 may also simply be made as a series of through-holes on MVC tray 112, simplifying the process of creating the cavities.

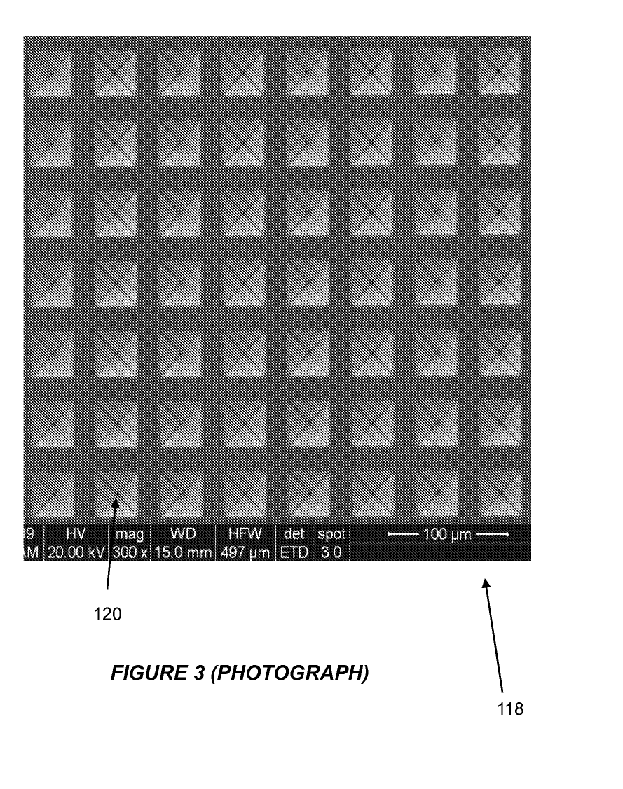

FIG. 3 illustrates a top-view SEM photo of MVC 118. MVC 118 is similar in structure to MVC 100 from FIG. 1. MVC 118 is made of a (100) mono-crystalline silicon wafer. With a patterned masking layer (oxide), pyramidal micro-scale cavities 120 are selectively and crystallographically etched in a heated KOH solution. The micro-scale cavities may or may not have the same sizes and depths, and their format could be conveniently designed in the photo mask layout and etching process control. As shown in this embodiment, cavities 120 are pyramidal in shape and all have approximately the same dimensions.

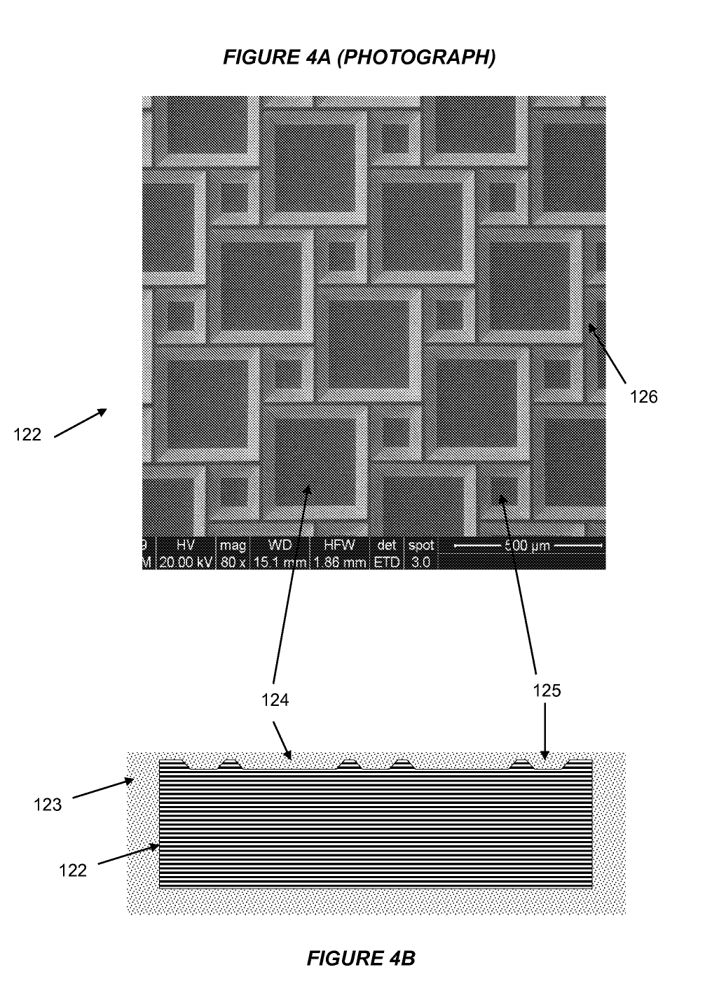

FIGS. 4A and 4B illustrate a top-view SEM photo and a cross-sectional schematic drawing, respectively, of MVC 122 in ambient air pressure environment 123. MVC 122 is also made of a (100) mono-crystalline silicon wafer. With a patterned masking layer (oxide), the pyramidal micro-scale cavities are etched in a heated KOH solution. Micro-scale cavities 124 are made larger but shallower, and their ridges 126 are narrower than the MVC shown in FIG. 3. MVC 122 also includes smaller cavities 125, interspersed among larger cavities 124. This arrangement of cavities allows for aligned bonding with a wafer having corresponding structures. The use of relatively shallow micro-scale cavities allows limited local deformation/deflection of a thin wafer when vacuum bonded. The local deformation/deflection is limited by the shallow depth of cavities 124 and 125. The relative large cavity openings and narrow top ridges reduce the top contact surface areas; as a result, the debonding/separating/declamping process tends to be easier and more reliable.

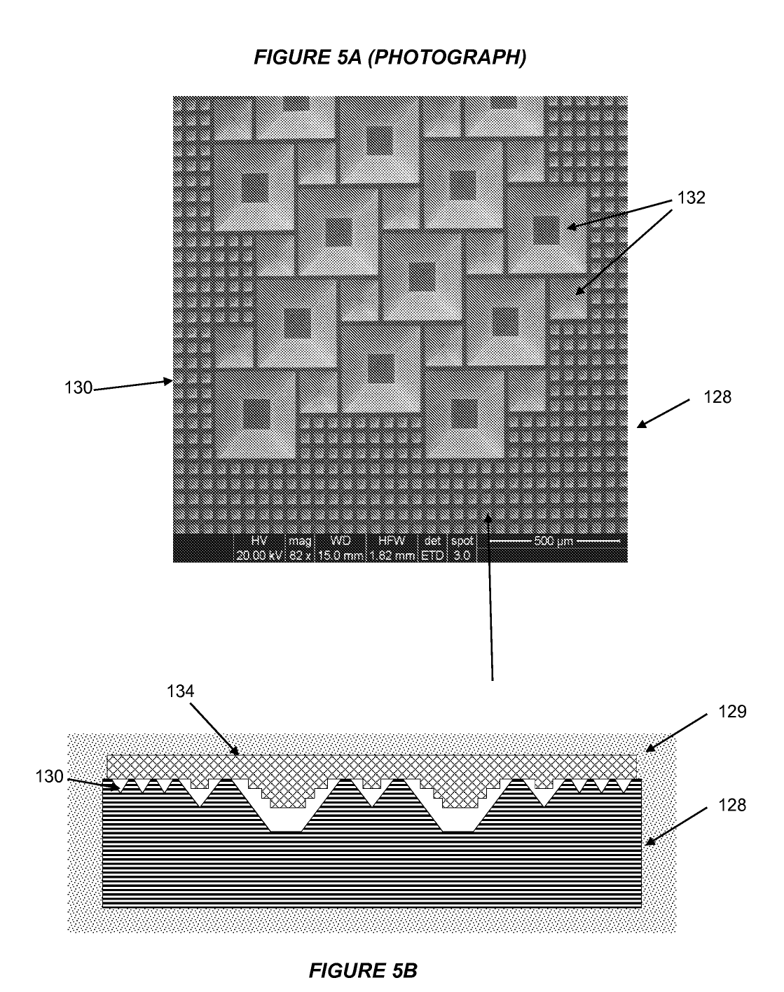

FIGS. 5A and 5B illustrate a top-view SEM photo and a cross-sectional schematic drawing MVC 128 in ambient air pressure environment 129. This type of MVC allows handling non-flat thin wafers with proper alignment. The MVC shown in this figure is also made of a (100) mono-crystalline silicon wafer. With a patterned masking layer (oxide), the pyramidal micro-scale cavities are etched in a heated KOH solution. The MVC in this figure consists of arrays of small cavities 130 that surround large and deeper cavities 132. In this embodiment, some of cavities 132 are pyramidal, and some are truncated pyramidal. This type MVC allows bonding of pre-structured thin wafer 134 with its bonding surface not planar. With proper alignment in the bonding apparatus, the out-of-plane features on thin wafer 134 are positioned in the larger of cavities 132 such that the wafer and the MVC properly align.

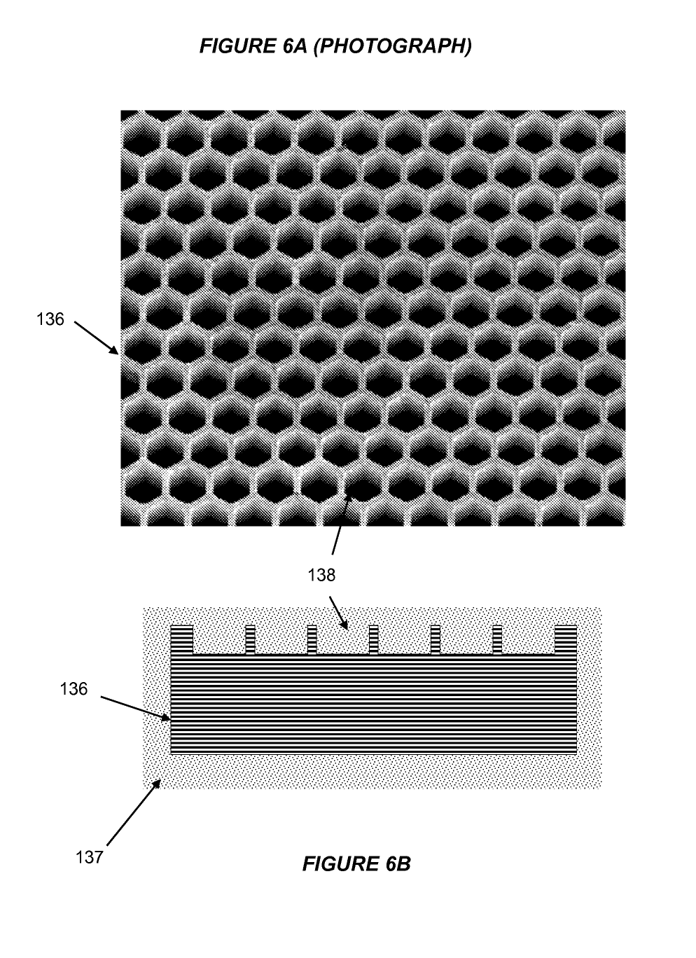

FIGS. 6A and 6B illustrate a top-view SEM photo and a cross-sectional schematic drawing of MVC 136 in ambient air pressure environment 137. MVC 136 is also made of a silicon wafer. Cavities 138 are etched by deep reactive ion etching (DRIE), such as using a Bosch process by using a patterned photoresist masking layer. Shown in this figure the micro-scale cavities are in a honeycomb hexagon shape. With this fabrication method, any desired lateral patterns/shapes can be made. The cavity shapes are not limited to the square pyramidal shapes as shown in previous FIGURES. A DRIE process can be used to make high aspect ratio deep cavities with substantially vertical thin walls. Alternatively, normal plasma silicon etching can also be used to make various shape cavities with non-vertical sidewalls.

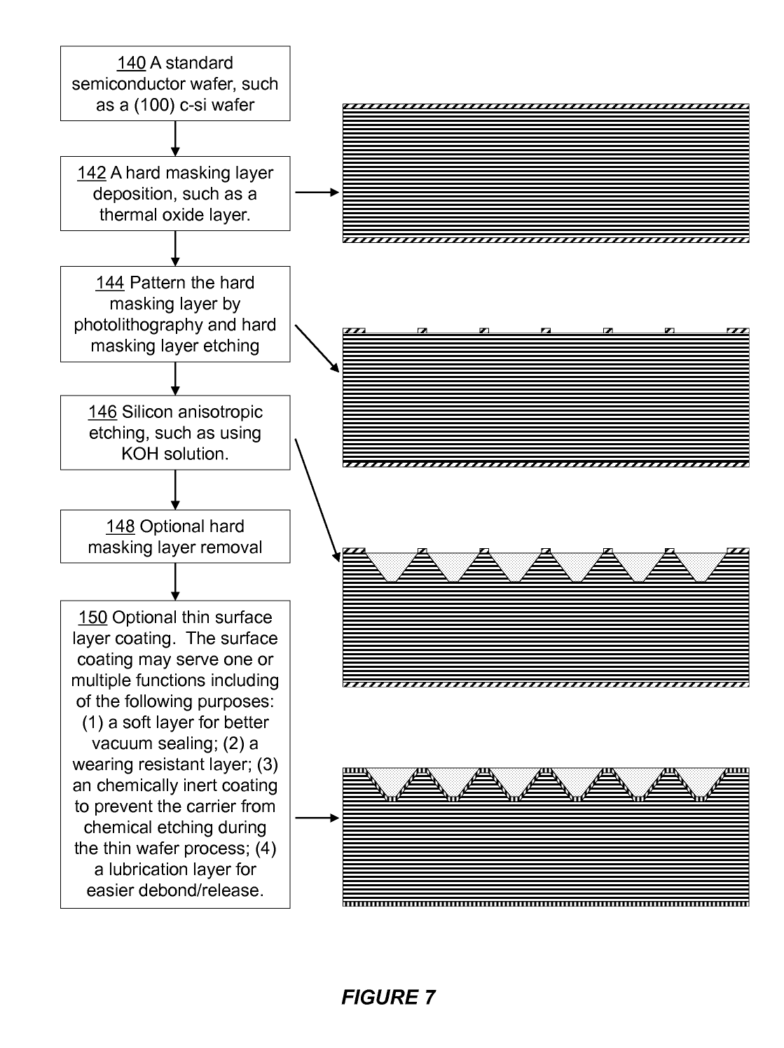

FIG. 7 illustrates key fabrication steps and cross-sectional schematic drawings after these steps in making one type of MVC. As shown, the schematic drawings correspond to an MVC in progress, after the indicated fabrication step has been completed.

At step 140, the fabrication process starts from a single-crystal (100) silicon wafer with polished or non-polished surfaces. The wafer shapes could be circular, square with truncated or rounded corners, rectangular, octagonal, hexagonal, or any other geometrical shape of interest. The MVC wafer size may typically be in the range of 100 mm to 300 mm (or even larger in size, particularly for batch trays) with thickness in the range of 0.5 mm to a few mm. The first fabrication process involves forming a hard masking layer at step 142, such as a thermally grown silicon dioxide (SiO₂) or LPCVD silicon nitride (SiNₓ), on the wafer surface. In one embodiment, the hard mask layer is formed on all the wafer exposed surfaces, and in another embodiment, the hard masking layer is formed only on the front wafer surface where the patterning are to be made. The hard masking layer thickness is typically between 0.1 micron and a few microns, in some embodiments between 0.1 micron and 1.5 microns.

At step 144, at least two possible embodiments may be used to pattern the hard masking layer. In one embodiment, a photoresist pattern is generated on top of the hard mask layer by photolithography steps including spin-coating (or spray coating), baking, aligned exposure and developing. In another embodiment, a soft mask layer with defined patterns is screen-printed on top of the hard mask layer for reduced fabrication costs. In both embodiments, the patterns are preferably aligned to the wafer (100) direction. In the next step, the exposed hard mask layer is chemically etched. For example, the photoresist pattern is transferred into the oxide layer by etching the exposed oxide with buffered HF solution. The oxide etching step may in some embodiments use a mechanical fixture for protecting the wafer edge and back surfaces from being etched. Alternatively, the etch process can be performed in a setup such that only the front wafer surface is exposed to the hard mask etching chemical. After that, the remaining photoresist layer is removed by plasma ashing or wet photoresist stripping. The patterned silicon dioxide layer is used as a hard mask layer during anisotropic silicon etching.

In step 146, anisotropic silicon etching, such as KOH, NaOH, or TMAH solutions is used to etch the exposed silicon area. Anisotropic wet etching of crystalline silicon is one of the key technologies for silicon micromachining. Due to differing chemical reactivity of certain crystal planes of the silicon, anisotropic etchants etch much faster in one direction than in another, exposing the slowest etching crystal planes over time. As an example, when etching a (100) silicon wafer with patterned hard mask particularly oriented, an anisotropic etching slows down markedly at (111) planes of silicon, relative to its etch rates for other planes. As a result, the etching exhibits flat surfaces and well-defined angles. One of the key advantages of using anisotropic wet silicon etching, such as KOH, is its repeatability and uniformity in silicon etching while maintaining a low production cost. In addition, when the KOH etching reaches (111) crystallographic planes, it etches the (111) planes with substantially slower etch rates. As a result, the manufacturing etching process is convenient to control with much wider process control windows and much lower cost than other silicon etching methods, such as DRIE silicon dry etching. In the embodiment wherein the wafer edge and backside surfaces are also covered with a hard mask layer, the wafers may be etched in a batch silicon etching solution. However, in the embodiment wherein the wafer edge or backside are exposed without hard mask layer, the wafer may be etched in a setup that only has the front side of the wafer being exposed to the silicon etching solution. After the silicon etching, the remaining hard mask layer is removed at step 148 by chemical etching, such as in an HF solution for oxide removal. Next, the etched silicon wafers may be cleaned in standard wafer cleaning processes, such as RCA1 and RCA2 cleanings.

At step 150, a LPCVD silicon nitride layer is deposited on both the front and back surfaces of the silicon MVC. That layer is in some embodiments in the range of 0.1 micron to a few microns, and in some embodiments in the range of 0.1 micron to 3 microns.

FIG. 8 illustrates key fabrication steps and cross-sectional schematic drawings after these steps in making another type of MVC.

As shown starting at step 152, this MVC is also made of a silicon wafer. At step 154, a photoresist pattern is generated on top of the silicon surface by photolithography steps including spin-coating (or spray coating), baking, aligned exposure and developing.

At step 156, cavities are etched by deep reactive ion etching (DRIE) using a Bosch process by using a patterned photoresist masking layer. Any shape may be used, but this embodiment demonstrates hexagonal cavities, such as those shown in FIGS. 6A and 6B. With this fabrication method, any other lateral patterns/shapes can be made. A DRIE process can be used to make high aspect ratio deep cavities with vertical thin walls. Alternatively, normal plasma silicon etching can be used to make various shape cavities with non-vertical sidewalls.

At step 158, the remaining photoresist masking layer is removed. After cleaning the surfaces, at step 160 an optional LPCVD silicon nitride layer is then coated on both the top and bottom surfaces of the fabricated silicon MVC.

Other methods without the use of photolithography may be used to fabricate MVCs. For instance, one may use direct-write laser ablation to form the array of micro-scale cavities, followed by cleaning and subsequent protective LPCVD silicon nitride deposition to fabricate the MVC.

FIGS. 7 and 8 describe fabrication processes for making silicon MVCs. Other materials, such as metals, ceramics, and polymers can also be used as MVC structural materials. The corresponding micro cavity making methods may include but are not limited to direct laser ablation, micro EDM, micro milling, controlled grinding, abrasive blasting, hot-embossing, stamping, and injection molding.

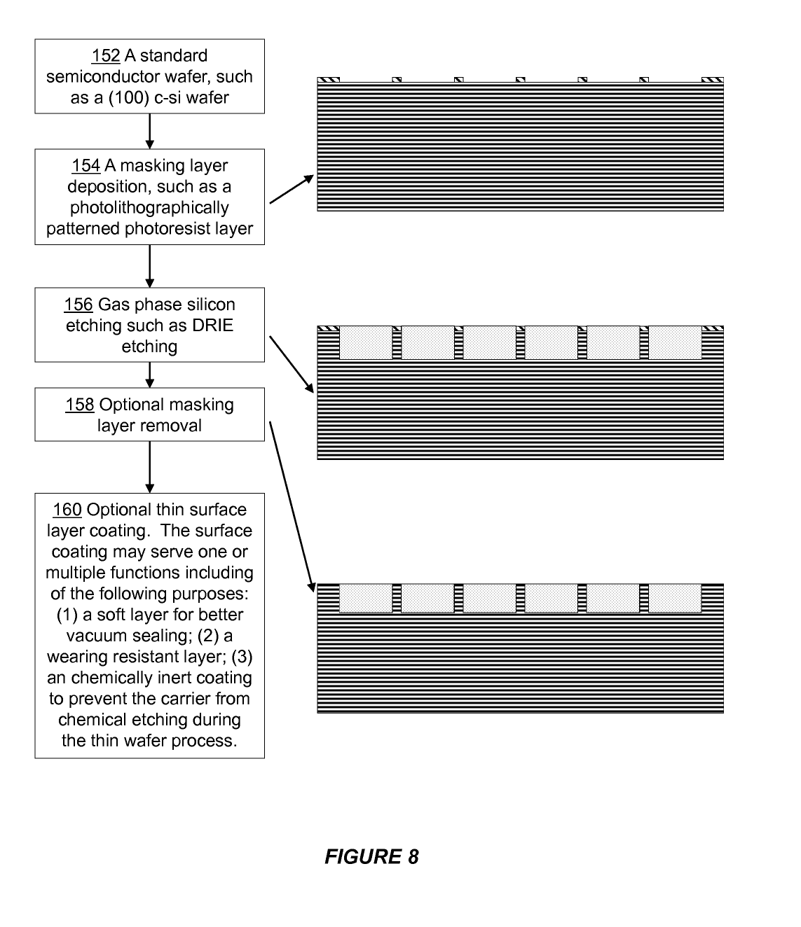

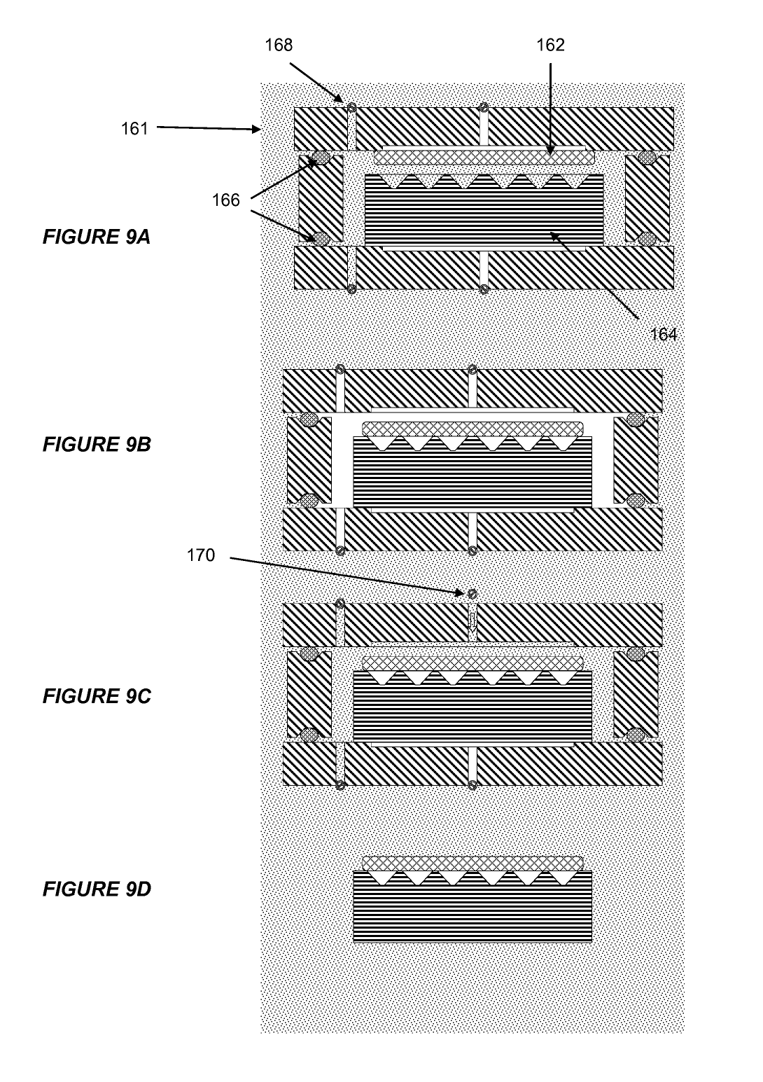

FIGS. 9A-9D illustrate an apparatus of the present disclosure and the sequence of using it for vacuum bonding a thin wafer to an MVC in ambient air pressure environment 161. Thin wafer 162 and MVC 164 are vacuum clamped/chucked to two separate plates. The vacuum chucking plates have normal surface grooves, channels, ports and valves for vacuum chucking a wafer, but they also consist of ports and valves outside the wafer coverage areas for pumping down and venting the chamber that formed between the top and bottom chucking plates. As shown in FIG. 9A, wafer 162 and MVC 164 are positioned face-to-face with a vacuum sealing mechanism, such as O-rings 166, in between. After this jig configuration is assembled, an enclosed small chamber is formed for evacuating the air between the aligned thin wafer and the MVC. It is to be noted that the top and bottom vacuum chucking plate may be made identical, so that they are interchangeable conveniently in multiple chucking and de-chucking manufacturing cycles. The enclosed chamber is then pumped down to a lower pressure. The pumping is conducted through the side vacuum port and valve on either the top or the bottom plate, as shown through port 168 in the top vacuum plate. The pressure of the chamber pumping down is monitored and controlled by pumps and pressure meters that are not shown in the drawings. Once a specific pressure, which may be similar to or lower than the thin wafer and MVC chucking vacuum pressure, is reached, the valve is closed and the chamber is sealed. As shown in FIG. 9B, after or during the pumping down, wafer 162 is released from the top vacuum plate and is placed on top of the sealing surface of MVC 164. This releasing of the thin wafer could be initiated by one or all of the following effects: once the chamber pressure is lower than the thin wafer and top plate vacuum chucking pressure, the thin wafer is forced down by the pressure differential; the weight of the thin wafer can assist the separation of the thin wafer from the top vacuum chucking plate; optional heating or ultrasonic vibration of the thin wafer through the top vacuum chucking plate can help the thin wafer separation from the top chucking plate when the low chamber pressure is reached. In the next step, as shown in FIG. 9C, the chamber may be vented through port 170 on the center of the top chucking plate. This method of center venting may help in the case when the thin wafer is not flat due to its internal mechanical stress and surface roughness/particles of this sealing surface. The inflow of air from the center port will force the initial vacuum bonding of the thin wafer from its center to edge. Once the chamber is fully vented, the thin wafer is also fully vacuum-bonded to the MVC surface. In the next step, as shown in FIG. 9D, the jig is disengaged and the now-bonded MVC 164 is de-chucked from its bottom vacuum chucking plate. The bonded thin wafer 162 is then ready for its subsequent fabrication process and handling.

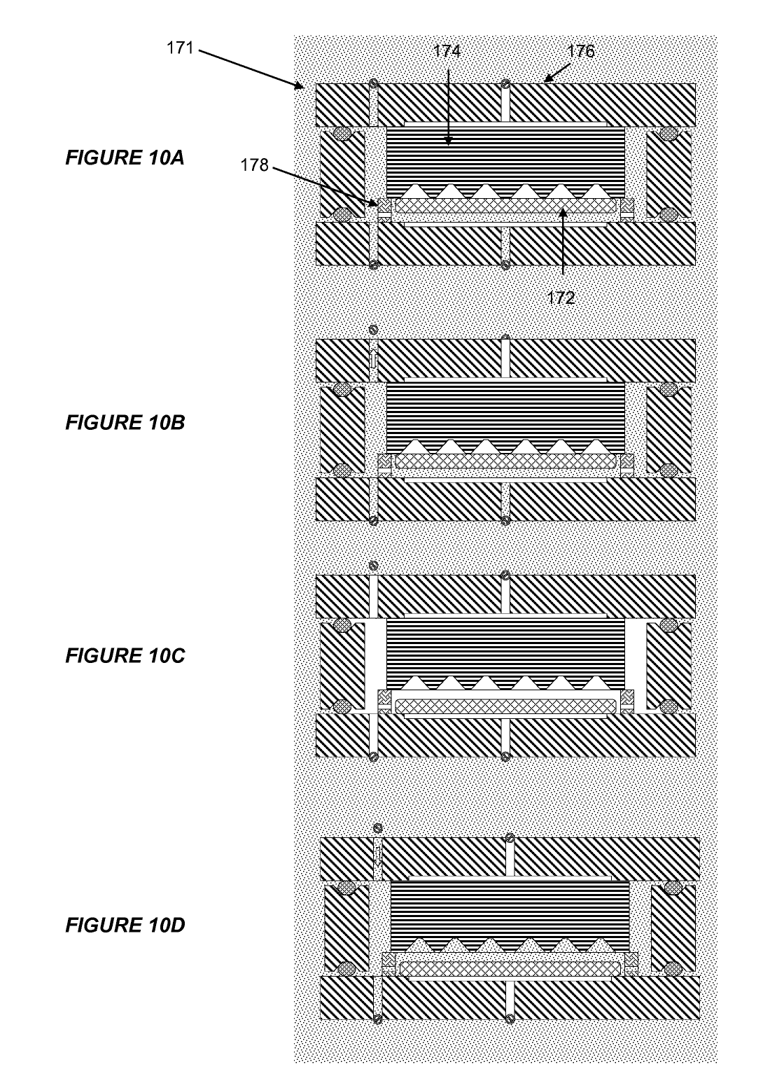

FIGS. 10A-10D illustrate an embodiment of the debonding/separating/declamping of a thin wafer from an MVC in ambient air pressure environment 171.

As shown in FIG. 10A, wafer 172 and MVC 174, bonded together, are vacuum-chucked to top plate 176 and then assembled on top of a bottom vacuum chucking plate or simply a flat surface with a vacuum sealing mechanism in between to form an enclosed chamber for the debonding process. It is to be noted that soft pedestal 178 is placed on the bottom plate to secure the MVC and physically separate the MVC from the thin wafer when the thin wafer is released and dropped on the bottom plate. As shown in FIG. 10B, the chamber is pumped down through one of the side port/valve on either the top or the bottom chucking plate. When a sufficiently low pressure is reached, shown in FIG. 10C, the thin wafer can be released by one of or all of the following effects: once the chamber pressure is lower than the micro vacuum cavity pressures, the thin wafer is forced down by the pressure differential; the weight of the thin wafer can assist the separation of the thin wafer from the MVC; optional heating or ultrasonic vibration of the thin wafer through the top vacuum chucking plate can help the thin wafer separation from the top chucking plate when the low chamber pressure is reached. As shown in FIG. 10C, the chamber and the space between the debonded thin wafer and MVC are vented through one of the side port/valve on either the top or bottom chucking plate. The separated thin wafer and its MVC are then vacuum-chucked on the top and bottom chucking plate respectively. The debonding jig is then dis-engaged and the thin wafer is sent to the next processing step.

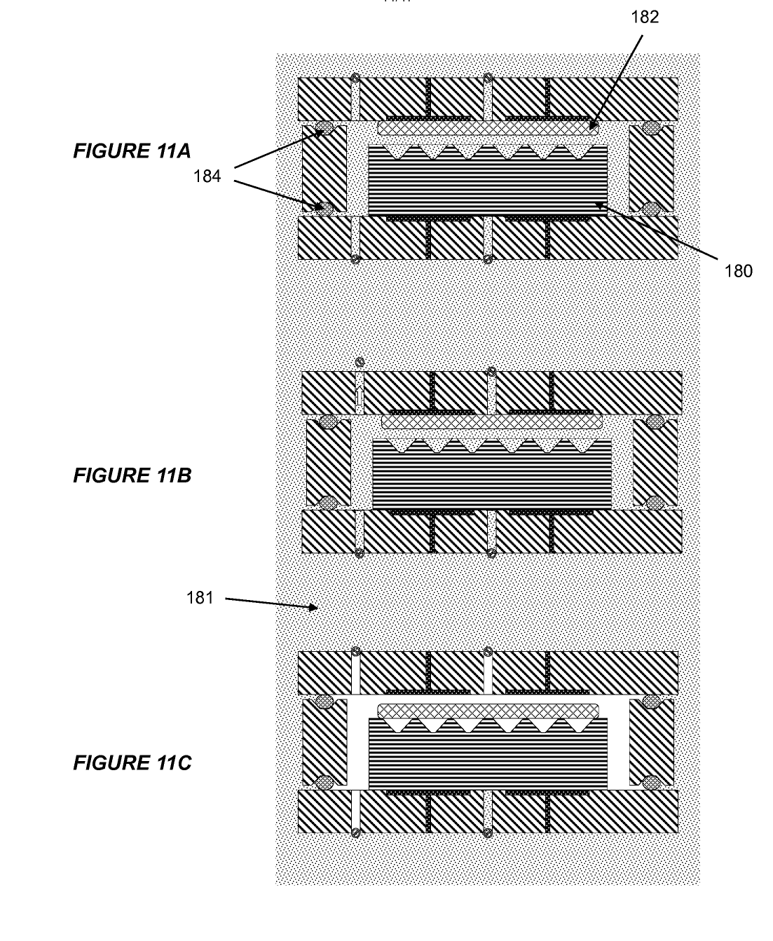

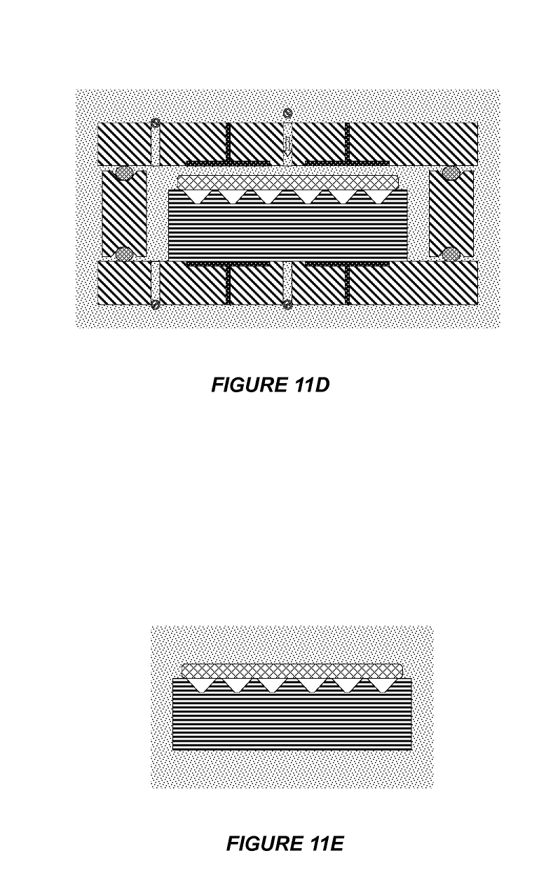

FIGS. 11A-11E illustrate another apparatus of the present disclosure and the sequence of using it for making the vacuum bonding of a thin wafer and a MVC in ambient air pressure environment 181. Thin wafer 182 and MVC 180 are electrostatically-chucked to two plates separately. The electrostatic chucking plates are either mobile or connect to their respective power supplies. Also there are ports and valves on the electrostatic chucking plates that are outside the wafer coverage areas for pumping down and venting the chamber that is formed between the two chucking plates. As shown in FIG. 11A, thin wafer 182 and MVC 180 are then positioned face-to-face with a vacuum sealing mechanism, such as O-ring 184, in between. After this jig configuration is assembled, an enclosed small chamber is formed for evacuating the air between the aligned thin wafer and the MVC. It is to be noted that the top and bottom chucking plate may be made identical, so that they are interchangeable conveniently in multiple chucking and de-chucking manufacturing cycles. FIG. 11B illustrates the pumping down of the enclosed chamber and the space between the aligned and separated thin wafer 182 and MVC 180. The pumping may be conducted through the side vacuum port and valve on either the top or the bottom plate. The pressure of the chamber pumping down is monitored and controlled by pumps and pressure meters that are not shown in the drawings. Once a specific low pressure of vacuum is reached, the valve is closed and the chamber is sealed. As shown in FIG. 11C, after the pumping down, the thin wafer is released from the top electrostatic plate and is placed on top of the MVC sealing surface. After turning off the electrostatic chucking voltage, the releasing of the thin wafer could be initiated by one or more of the following effects: once the chamber pressure is lower than the pressure in air pockets between the thin wafer and its top electrostatic chucking plate, the thin wafer is forced down by the pressure differential; the weight of the thin wafer can assist the separation of the thin wafer from the top electrostatic chucking plate; optional heating or ultrasonic vibration of the thin wafer through the top electrostatic chucking plate can help the thin wafer separation from the top chucking plate when the low chamber pressure is reached. In the next step, as shown in FIG. 11D, the chamber may be vented through the port/valve on the center of the top chucking plate. This method of center venting will help in the case when the thin wafer is not flat due to its internal mechanical stress and surface roughness/particles of this sealing surface. The inflow for air from the center port will force the initial vacuum bonding of the thin wafer from its center to edge. Once the chamber is fully vented, the thin wafer is also fully vacuum-bonded to the MVC surface. In the next step, as shown in FIG. 11E, the jig is dis-engaged and the bonded MVC is de-chucked from its bottom electrostatic chucking plate. The bonded thin wafer is then ready for its subsequent fabrication process and handling.

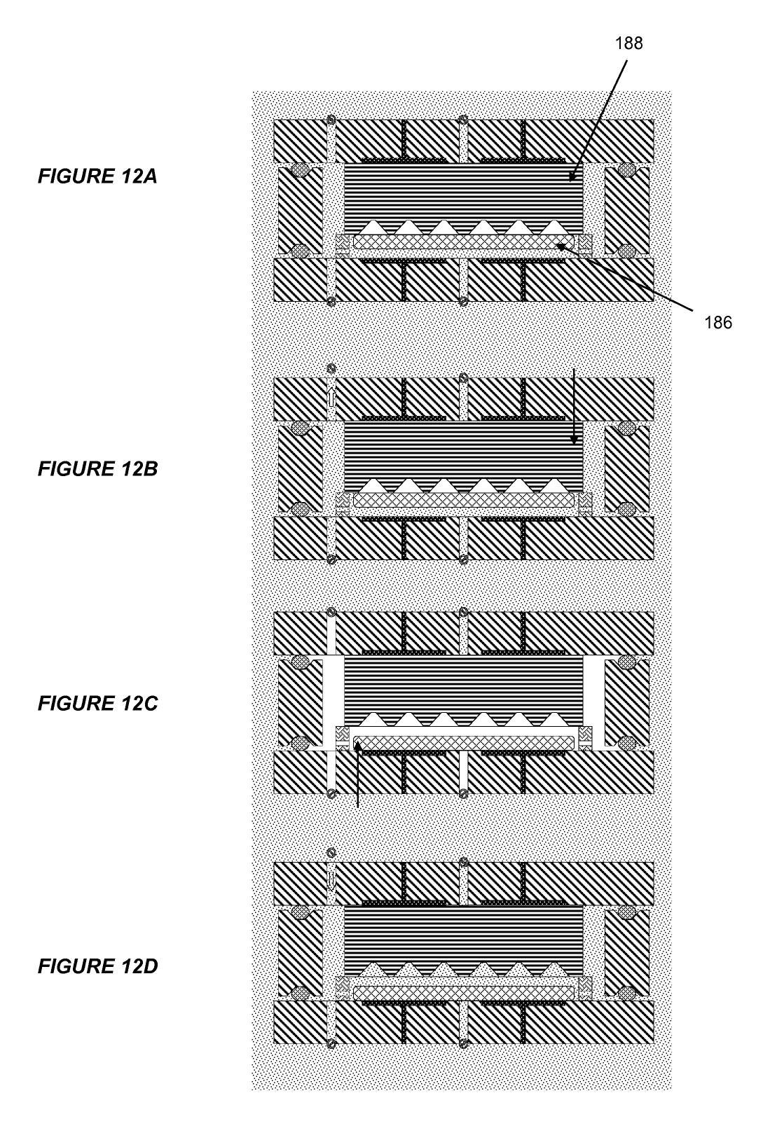

FIGS. 12A-12D illustrate another apparatus of the present disclosure and the sequence of using it for debonding/separating/declamping of thin wafer 186 from MVC 188. Cross-sectional schematic drawings after key steps are shown. As shown in FIG. 12A, the thin-wafer bonded MVC is electrostatically-chucked to the top plate and then assembled on top of bottom electrostatic chucking plate or simply a flat surface with a vacuum sealing mechanism in between to form an enclosed chamber for the debonding process. It is to be noted that there is a soft pedestal placed on the bottom plate. The soft pedestal is used to secure the MVC and physically separate the MVC from the thin wafer when the thin wafer is released and dropped on the bottom plate. As shown in FIG. 12B, the chamber may be pumped down through one of the side port/valve on either the top or the bottom chucking plate. When a low pressure or vacuum equivalent or lower than the pressures in the micro vacuum cavities of the MVC, the thin wafer can be released by one of or more of the following effects: once the chamber pressure is lower than the micro vacuum cavity pressures, the thin wafer is forced down by the pressure differential; the weight of the thin wafer can assist the separation of the thin wafer from the MVC; optional heating or ultrasonic vibration of the thin wafer through the top electrostatic chucking plate can help the thin wafer separation from the top chucking plate when the low chamber pressure is reached. As shown in FIG. 12C, the chamber and the space between the debonded thin wafer and MVC are vented through one of the side port/valve on either the top or bottom chucking plate. The separated thin wafer and its MVC are electrostatic-chucked on the top and bottom chucking plate respectively. The debonding jig is then dis-engaged and the separated MVC and thin wafer is sent to the next processing step.

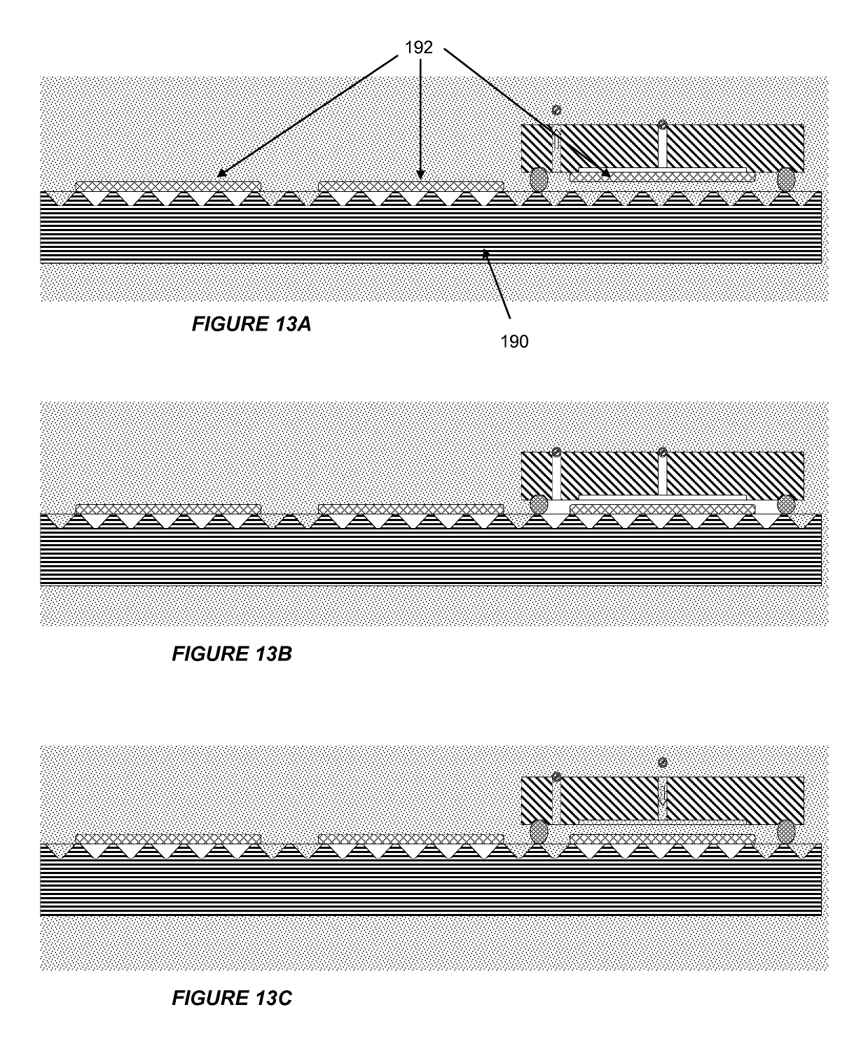

FIGS. 13A-13C illustrate another apparatus of the present disclosure and the sequence of using it for making the vacuum bonding of multiple thin wafers 192 and MVC tray 190. Cross-sectional schematic drawings after key steps are shown. One of thin wafers 192 is vacuum chucked on a vacuum chucking plate that has normal surface grooves, channels, ports and valves for vacuum chucking a wafer, but it also consists of ports and valves outside the wafer coverage areas for pumping down and venting the chamber that formed between the top chucking plates and MVC tray 190. As shown in FIG. 13A, the vacuum chucked thin wafer is positioned with a vacuum sealing mechanism, such as an O-ring, in between. After this jig configuration is assembled, an enclosed small chamber is formed for evacuating the air between the thin wafer and the MVC tray. As shown in FIG. 13B, the enclosed chamber and the space between the thin wafer and the MVC tray is pumped down. The pumping may be conducted through the side vacuum port and valve on the top chucking plate. The pressure of the chamber pumping down is monitored and controlled by pumps and pressure meters that are not shown in the drawings. Once a specific low pressure of vacuum, which is similar or lower than the thin wafer chucking vacuum pressure, is reached, the valve is closed and the chamber is sealed. After or during the pumping down, the thin wafer is released from the top vacuum plate and is placed on top of the MVC sealing surface. This releasing of the thin wafer may be initiated by one or more of the following effects: once the chamber pressure is lower than the thin wafer and top plate vacuum chucking pressure, the thin wafer is forced down by the pressure differential; the weight of the thin wafer can assist the separation of the thin wafer from the top vacuum chucking plate; optional heating or ultrasonic vibration of the thin wafer through the top vacuum chucking plate can help the thin wafer separation from the top chucking plate when the low chamber pressure is reached. In the next step, as shown in FIG. 13C, the chamber may be vented through the port/valve on the center of the top chucking plate. This method of center venting will help in the case when the thin wafer is not flat due to its internal mechanical stress and surface roughness/particles of this sealing surface. The inflow of air from the center port will force the initial vacuum bonding of the thin wafer from its center to edge. Once the chamber is fully vented, the thin wafer is also fully vacuum-bonded to the MVC surface. In the next step, the jig is disassembled for the next thin wafer bonding and the bonded thin wafers are then ready for subsequent fabrication processes and handling.

It is to be noted that the bonding of multiple thin wafers on a MVC tray in this figure may also be realized by using electrostatic-chucking of the thin wafers.

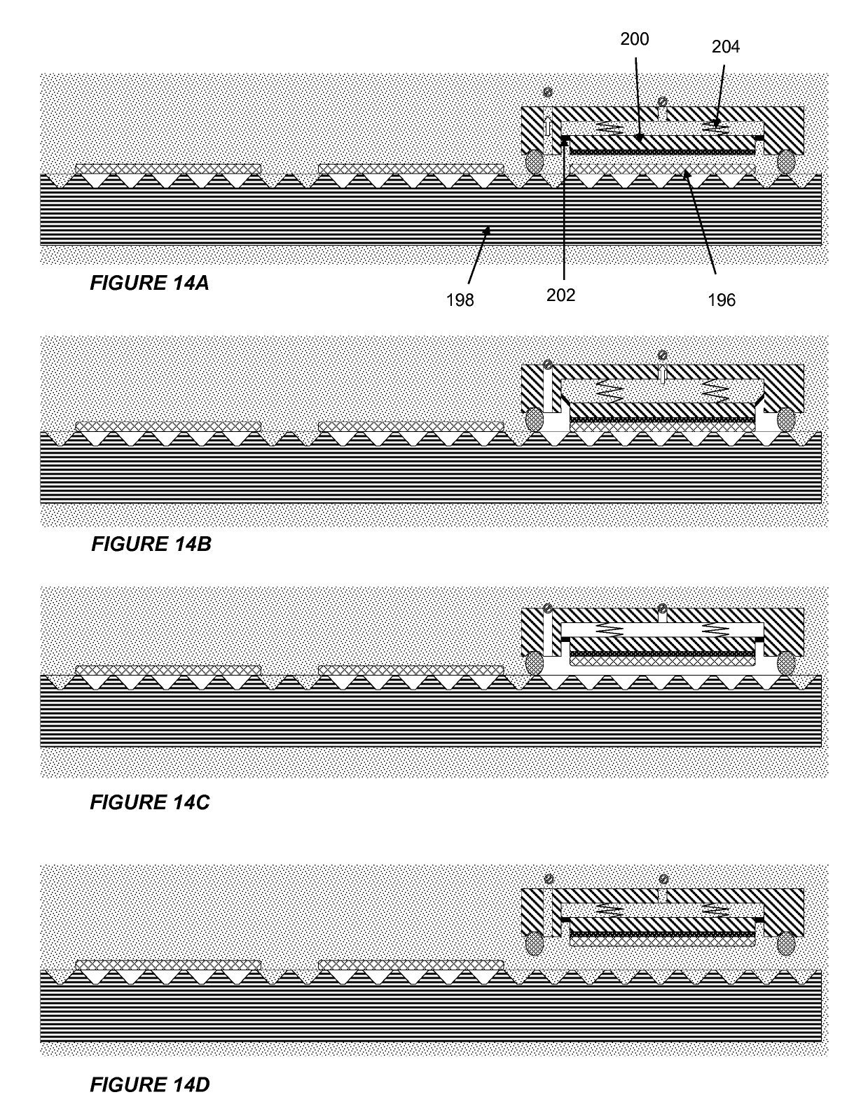

FIGS. 14A-14D illustrate another apparatus of the present disclosure and the sequence of using it for debonding/separating of multiple thin wafers 196 from MVC tray 198. Cross-sectional schematic drawings after key steps are shown. As shown in FIG. 14A, top chucking plate 200 is deflectable and is connected to deflectable diaphragm 202 on its edge and springs 204 on its top side. Also there is an enclosed inner chamber on top of the deflectable top chucking plate. Chucking plate 200 could be an electrostatic chuck or a regular chuck with adhesive bottom surface for grabbing the thin wafer during debonding. The chuck assembly is positioned on top of a thin wafer to be debonded from the MVC tray. As shown in FIG. 14B, the chamber between the top chucking plate and the MVC is pumped down from the side port/valve on the top plate. During pumping down the chuck is moved downwards and the springs are pulled due to the pressure deferential across the chuck. When the adhesive/electrostatic chuck surface makes contact with the thin wafer top surface, the thin wafer is connected to the deflectable chuck. After a lower than micro-vacuum-cavity pressure is reached in the outer chamber, the inner chamber is then pumped down. During the inner chamber pumping down, the spring restoring forces will pull the deflectable chucking plate up with the thin wafer. As a result, as shown in FIG. 14C, the thin wafer is separated from the MVC tray in the vacuum. In the next step, as shown in FIG. 14D, the outer chamber is vented first followed by the inner chamber venting. After the outer chamber venting, the jig assembly can be removed from the MVC tray and the debonded thin wafer can be transferred in the next handling step.

It is to be noted that the apparatus for debonding in this figure can also be used for vacuum bonding of a thin wafer to its MVC, especially when electrostatic-chucking is used to chuck the thin wafer prior to the vacuum bonding. The apparatus of this method can also be used to debond a thin wafer from a single wafer MVC. The drawings of this apparatus in vacuum bonding process in not shown but it is part of the present disclosure.

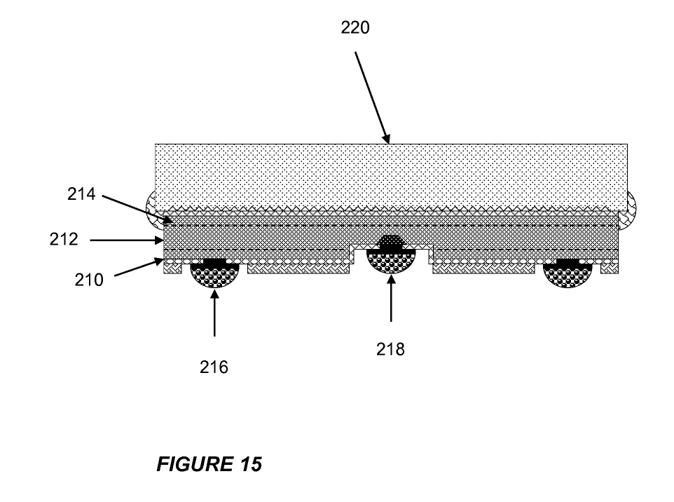

FIG. 15 illustrates a cross-sectional schematic drawing of a solar cell based on a thin silicon substrate. The thin silicon substrate is made from an epitaxial silicon growth process. The thin silicon is mono-crystalline and consists of in-situ doped n-type base 210, p⁺ emitter 212, and n⁺ front surface field (FSF) layer 214. Both the emitter contacts 216 and base contacts 218 are made on the backside of the solar cell. The thin silicon solar cell is reinforced by glass MVC 220 that is mounted on its front side. The edge interface of the thin silicon substrate and the glass MVC is sealed in an adhesive, such as EVA or PV grade silicone to prevent chipping and cracking of the thin silicon substrate at its edges. On the front silicon surface, there is a thin thermal silicon oxide layer for silicon surface passivation and a thin PECVD silicon nitride layer for anti-reflection coating (ARC). The micro cavity surface on the glass MVC is also served as a light trapping layer to reduce the front reflective optical loss. On the backside of the solar cell there is a coated reflective insulator layer to reduce the transmission loss on the backside surfaces. The fabrication process of this solar cell also serves as an exemplary application of the MVC methods and apparatus of the present disclosure. In particular, the MVC could be used as a temporary carrier for thin substrate handling and processing.

The present disclosure is useful in, among other areas, the field of solar cells based on thin-film solar substrates (TFSSs). Methods of making such solar cells are disclosed in U.S. Pub. Nos. 2008/0157283 and 2009/0107545, which are hereby incorporated by reference.

A border definition trench may be made on the peripheral of an active wafer area to facilitate the release. U.S. Pub. No. 2010/0203711, which is incorporated by reference, discloses in detail methods of making the border definition trenches.

U.S. Pat. No. 7,745,313 titled “SUBSTRATE RELEASE METHODS AND APPARATUSES,” which is incorporated by reference, discloses in detail methods of releasing the epitaxial layer to form a TFSS.

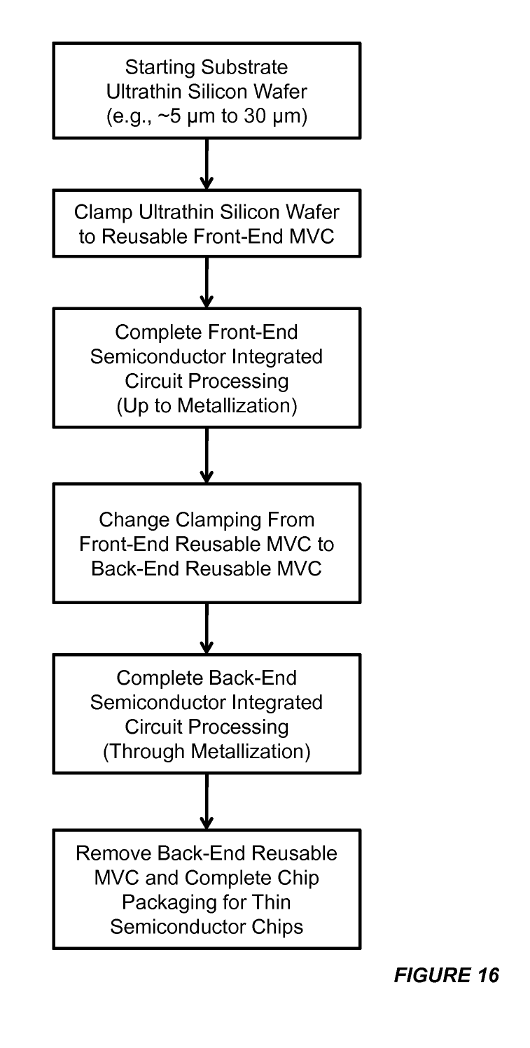

Besides solar photovoltaics, the MVC apparatus and methods of this disclosure can be applied to semiconductor microelectronics and integrated circuit fabrication. FIG. 16 illustrates such application in a modern semiconductor device such as CMOS IC fabrication. The MVC enables the use of much lower cost and much thinner silicon wafers (e.g., thinner than 30 microns) compared to standard thick wafers (over 700 microns). This results in a substantial reduction of the silicon material cost. A typical CMOS process flow may use two reusable MVCs: one for the front-end processing (up to metallization), and the other one for back-end metallization. The use of multiple (e.g., 2) MVCs will ensure cross-contamination-free manufacturing of cost-reduced integrated circuits.

Those with ordinary skill in the art will recognize that the disclosed embodiments have relevance to a wide variety of areas in addition to those specific examples described above.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A mobile vacuum carrier for supporting a thin wafer, said mobile vacuum carrier comprising:
a structural substrate having a top surface, a thickness approximately in the range of 0.5 millimeters to 5 millimeters, and a substrate width approximately in the range of 10 millimeters to 500 millimeters;
a plurality of micro vacuum cavities disposed on said top surface, wherein said plurality of micro vacuum cavities corresponds to a surface texturing on said thin wafer; and
a thin surface coating layer deposited on said top surface and being substantially conformal to said plurality of micro vacuum cavities,
wherein said mobile vacuum carrier is capable of bonding to said thin wafer when said plurality of micro vacuum cavities is at a lower-than-ambient pressure.

2. The mobile vacuum carrier of claim 1, wherein said structural substrate and said thin wafer are made of two materials with substantially similar coefficients of thermal expansion to enable reliable thermal processing.

3. The mobile vacuum carrier of claim 1, wherein said structural substrate and said thin wafer are made of two materials with similar or different coefficients of thermal expansion for non-thermal processes.

4. The mobile vacuum carrier of claim 1, wherein said structural substrate and said thin wafer are made of a single material.

5. The mobile vacuum carrier of claim 1, wherein said structural substrate comprises a flexible material.

6. The mobile vacuum carrier of claim 1, wherein said plurality of micro vacuum cavities has a depth and a width at most approximately the same as the thickness of said thin wafer.

6. The mobile vacuum carrier of claim 2, wherein said depth and said width are at most approximately 100 microns.

7. The mobile vacuum carrier of claim 2, wherein said thickness, said depth, and said width are in the range of approximately a few microns to several hundred microns.

8. The mobile vacuum carrier of claim 1, wherein said structural material comprises monocrystalline or polycrystalline silicon.

9. The mobile vacuum carrier of claim 1, wherein said plurality of micro vacuum cavities comprises a plurality of pyramidal micro vacuum cavities.

11. The mobile vacuum carrier of claim 1, wherein said plurality of micro vacuum cavities comprises a plurality of hexagonal micro vacuum cavities.

12. The mobile vacuum carrier of claim 1, wherein said plurality of micro vacuum cavities comprises a plurality of pyramidal micro vacuum cavities and a plurality of truncated pyramidal micro vacuum cavities.

13. The mobile vacuum carrier of claim 1, wherein said structural substrate has a substrate length at least three times as long as said thin wafer, thereby comprising a tray capable of bonding to a plurality of thin wafers.

14. A method of reinforcing a thin wafer, said method comprising:
chucking said thin wafer to a wafer chuck;
chucking a mobile vacuum carrier to a mobile vacuum carrier chuck, wherein said mobile vacuum carrier comprises a structural substrate having a top surface, a plurality of reduced pressure cavities disposed on said top surface, and a thin surface coating layer deposited on said top surface and being substantially conformal to said plurality of reduced pressure cavities;
placing said chucked thin wafer and said chucked mobile vacuum carrier inside a vacuum chamber, said vacuum chamber comprising at least a sealing O-ring;
reducing the pressure inside said vacuum chamber via a vacuum port in said vacuum chamber;
releasing said thin wafer from said wafer chuck;
whereby said thin wafer rests on said mobile vacuum carrier;
venting said vacuum chamber via a vacuum port in said vacuum chamber, thereby bonding said thin wafer to said mobile vacuum carrier; and
removing said supported thin wafer and mobile vacuum carrier from said vacuum chamber.

15. The method of claim 14, wherein said step of releasing said thin wafer from said wafer chuck comprises releasing via a pressure differential.

16. The method of claim 14, wherein said step of releasing said thin wafer from said wafer chuck comprises releasing via a gravitational force.

17. The method of claim 14, wherein said step of releasing said thin wafer from said wafer chuck comprises releasing via heating said thin wafer.

18. The method of claim 14, wherein said step of releasing said thin wafer from said wafer chuck comprises releasing via an ultrasonic excitation of said thin wafer.

19. The method of claim 14, wherein said mobile vacuum carrier chuck and said wafer chuck comprise vacuum chucks.

20. The method of claim 14, wherein said mobile vacuum carrier chuck and said wafer chuck comprise electrostatic chucks.

21. The method of claim 14, further comprising debonding said thin wafer from said mobile vacuum carrier via the steps of:
placing said bonded thin wafer and mobile vacuum carrier inside a second vacuum chamber;
reducing the pressure inside said second vacuum chamber via a vacuum port in said second vacuum chamber;
detaching said thin wafer from said mobile vacuum carrier via a vacuum chucking process, an electrostatic chucking process, or an adhesive bonding process;
venting said second vacuum chamber via a vacuum port in said second vacuum chamber; and
removing said thin wafer and said mobile vacuum carrier from said second vacuum chamber.

22. An apparatus for vacuum bonding and debonding of a thin wafer and a mobile vacuum carrier, said apparatus comprising:
a vacuum chamber comprising at least an O-ring;
a thin wafer chuck inside said vacuum chamber;
a mobile vacuum carrier chuck inside said vacuum chamber;
a port coupled to said vacuum chamber;
a controlled valves coupled to said plurality of ports;
a pump coupled to said port, said pump operable to reduce an air pressure inside said vacuum chamber;
said port, said controlled valve, and said pump operable to attach said thin wafer and said mobile vacuum carrier together by reducing and increasing said air pressure inside said vacuum chamber; and
said port, said controlled valve, and said pump operable to detach said thin wafer and said mobile vacuum carrier.

23. The apparatus of claim 22, wherein said thin wafer chuck and said mobile vacuum carrier chuck comprise vacuum chucks.

24. The apparatus of claim 22, wherein said thin wafer chuck and said mobile vacuum carrier chuck comprise electrostatic chucks.

25. The apparatus of claim 22, wherein:
said mobile vacuum carrier comprises:
a (100) monocrystalline silicon structural substrate having a top surface, a thickness approximately in the range of 0.5 millimeters to 5 millimeters, and a substrate width approximately in the range of 100 millimeters to 300 millimeters;
a plurality of pyramidal micro vacuum cavities disposed on said top surface, wherein said plurality of micro vacuum cavities corresponds to a surface texturing on said thin wafer and have depths and widths at most approximately 100 microns; and
a thin surface coating layer deposited on said top surface and being substantially conformal to said plurality of micro vacuum cavities;
and further wherein said substrate comprises monocrystalline silicon.

26. A mobile vacuum carrier for supporting at least one thin wafer, said at least one thin wafer having two sides, and said mobile vacuum carrier comprising:
a structural substrate having a support surface,
a plurality of reduced pressure cavities disposed on said support surface; and
wherein said mobile vacuum carrier is capable of supporting said at least one thin wafer when said plurality of reduced pressure cavities is in contact with one side of said thin wafer at a first gas pressure lower than a second gas pressure on the opposite side of said thin wafer, creating a differential supporting pressure.

27. The mobile vacuum carrier of claim 26, wherein the pressure difference between said second and first gas pressures is substantially preserved by said mobile vacuum carrier during a period of supporting said at least one thin wafer.

28. The mobile vacuum carrier of claim 26, wherein said second gas pressure is an ambient atmospheric pressure.

29. The mobile vacuum carrier of claim 26, wherein said first gas pressure is in the range of approximately 0.1 Torr to 700 Torr.

30. The mobile vacuum carrier of claim 26, wherein said differential supporting pressure can be eliminated to terminate said supporting and to enable removal of said at least one thin wafer from said mobile vacuum carrier on demand.

31. The mobile vacuum carrier of claim 26, wherein said mobile vacuum carrier is capable of being reused multiple times for supporting and releasing a plurality of thin wafers through multiple reuse cycles.

32. The mobile vacuum carrier of claim 31, wherein said multiple reuse cycles comprise at least a wet process performed on said plurality of thin wafers.

33. The mobile vacuum carrier of claim 31, wherein said multiple reuse cycles comprise at least a thermal process performed on said plurality of thin wafers.

34. The mobile vacuum carrier of claim 31, wherein said multiple reuse cycles comprise at least a thin-film deposition process performed on said plurality of thin wafers.

35. The mobile vacuum carrier of claim 31, wherein said support surface has a plurality of neighboring three-dimensional surface features.

36. The mobile vacuum carrier of claim 26, wherein said support surface has at least one surface coating film.

37. The mobile vacuum carrier of claim 36, wherein said at least one surface coating film facilitates maintaining and preserving said differential supporting pressure through effective sealing of said reduced pressure cavities.

38. A mobile vacuum carrier for supporting at least one thin semiconductor die, said at least one thin semiconductor die having two sides, and said mobile vacuum carrier comprising:
a structural substrate having a support surface,
a plurality of reduced pressure cavities disposed on said support surface; and
wherein said mobile vacuum carrier is capable of supporting said at least one thin semiconductor die when said plurality of vacuum cavities is in contact with one side of said thin semiconductor die at a gas pressure lower than the gas pressure on the opposite side of said thin semiconductor die.
